(19) United States
(12) Patent Application Publication
(10) Pub. No.: US 2022/0200561 A1
(43) Pub. Date: Jun. 23, 2022

(54) IMPEDANCE MATCHING DEVICE

(71) Applicant: Motomu MATSUNAGA, Tokyo (JP)

(72) Inventor: Motomu MATSUNAGA, Tokyo (JP)

(21) Appl. No.: 17/432,726

(22) PCT Filed: May 12, 2020
(86) PCT No.: PCT/JP2020/018970

§ 371 Date: Aug. 20, 2021

(30) Foreign Application Priority Data
May 15, 2019 (JP) 2019-091934

(51) Int. Cl. H03H 7/40; H05H 1/46; H03H 7/46

(52) U.S. Cl. CPC H03H 7/40; H03H 7/46; H05H 1/4645

(57) ABSTRACT

An impedance matching device 2A connected between one or more plasma generating electrodes 51, 52 and a RF power supply 1 that selectively supplies RF power of multiple frequencies includes multiple matching devices 31, 32 each of which corresponds to each frequency of the multiple frequencies of the RF power, and matches an impedance of the RF power supply 1 to an impedance of a plasma load, and a demultiplexer 20 that demultiplexes the RF power of multiple frequencies output by the RF power supply 1 and feeds each of the demultiplexed RF power to a corresponding matching device in the multiple matching devices 31, 32.

### TECHNICAL FIELD

The disclosure relates to an impedance matching device for use in generation of plasma.

### BACKGROUND ART

Plasma generating apparatuses that generate plasma by supplying radiofrequency (RF) power to plasma generating electrodes are known. When RF power is supplied to a load that generates plasma (plasma load), the impedance of the RF power supply and the plasma load must be mutually matched in order to achieve high power supply efficiency.

In recent years, a method of switching the frequency of RF power supplied to a plasma load with multiple frequencies is used in plasma generating apparatuses, wherein the RF power is supplied to the plasma load through multiple impedance matching devices each one of which corresponding to respective one of the multiple frequencies.

A plasma generating apparatus that selectively uses multiple frequencies is equipped with a switch disposed between an RF power supply and multiple impedance matching devices to switch the RF power supply path to one of the impedance matching devices in order to supply RF power to the plasma load through an impedance matching device that matches the selected frequency.

In the related art, a microwave power supply for plasma generation is known that outputs microwave while periodically switching the path of the microwave output from the microwave power supply to multiple antennas using a microwave switch (see Patent Document 1).

### CITATION LIST

### Patent Document

[Patent Document 1] JP H9-274999

### DISCLOSURE OF THE INVENTION

### Problems to be Solved by the Invention

As a mechanical switch such as a coaxial switch is used in the plasma generating apparatus shown above that selectively uses multiple frequencies, when the frequency of RF power is switched, a momentary interruption occurs in the RF power supplied to the plasma generating electrodes, and such interruption can extinguish generated plasma.

In response to the above issue, it is an object of the present invention to provide an impedance matching device that can switch the frequency of RF power without causing a momentary interruption in the RF power supplied to plasma generating electrodes.

### Means for Solving the Problems

In response to the above issue, an example embodiment of the impedance matching device of the present invention is connected between one or more plasma generating electrodes and a RF power supply that selectively supplies RF power of multiple frequencies that includes multiple matching devices each of which corresponds to each frequency of the multiple frequencies of the RF power, and matches an impedance of the RF power supply to an impedance of a plasma load, and a demultiplexer that demultiplexes the RF power of multiple frequencies output by the RF power supply and feeds each of the demultiplexed RF power to a corresponding matching device in the multiple matching devices.

### Advantageous Effects of the Invention

An aspect of the present invention provides an impedance matching device that can switch the frequency of RF power without causing a momentary interruption in the RF power supplied to plasma generating electrodes.

### BRIEF DESCRIPTION OF THE DRAWINGS

FIG. 1 is a block diagram of a plasma generating apparatus for the first embodiment.

FIG. 2 is a block diagram of a plasma generating apparatus for the second embodiment.

### BEST MODE FOR CARRYING OUT THE INVENTION

An impedance matching device according to an embodiment of the present invention will now be described with reference to the drawings.

### First Embodiment

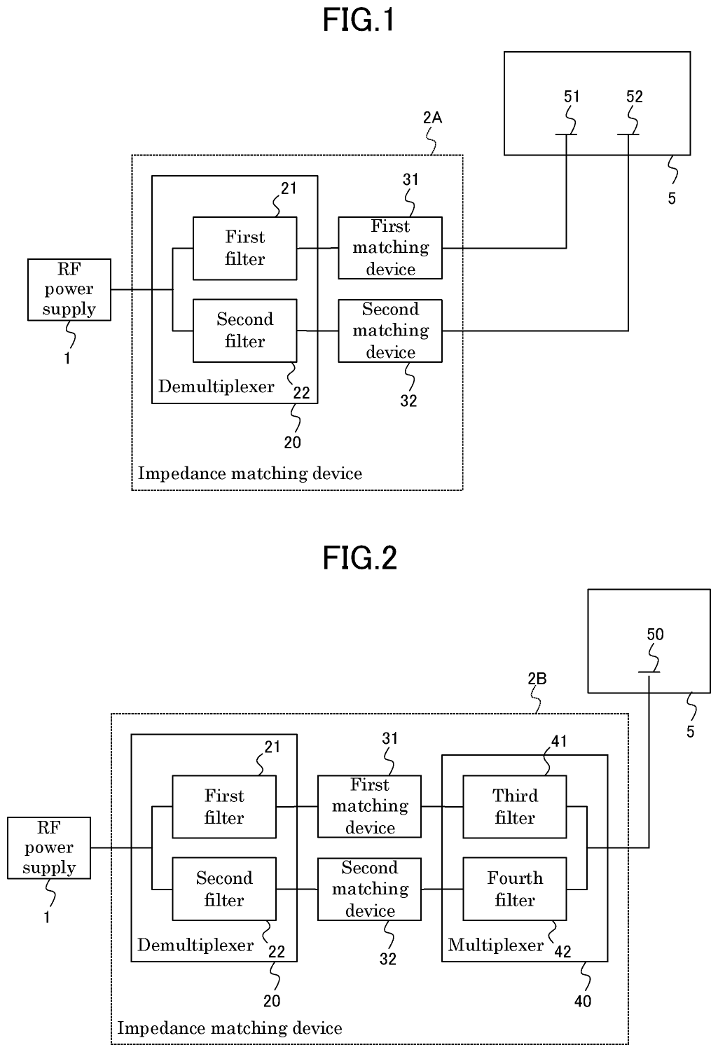

A plasma generating apparatus for a first embodiment is described. FIG. 1 is a block diagram of the plasma generating apparatus for the first embodiment.

As shown in FIG. 1, the plasma generating apparatus of this embodiment includes an RF power supply 1, an impedance matching device 2A, and a plasma space 5. A space for generating plasma is defined inside the plasma space 5, and two plasma generating electrodes 51 and 52 are disposed therein, which are supplied with RF power to generate plasma in the plasma space 5.

The impedance matching device 2A matches the impedance of the plasma load generated in the plasma space 5 to the impedance of the transmission line disposed at the RF power supply 1 side. The impedance matching device 2A includes a demultiplexer 20, a first matching device 31, and a second matching device 32. The demultiplexer 20 is configured as a diplexer in this embodiment, and has a first filter 21 that passes only RF power in a frequency band that includes a first frequency, and a second filter 22 that passes only RF power in another frequency band that includes a second frequency.

RF power of multiple and mutually different frequencies is output from the RF power supply 1 and supplied to the two plasma generating electrodes 51 and 52. In this embodiment, the RF power supply 1 outputs RF power in a first frequency or a second frequency as the multiple frequencies.

The RF power supply 1 is connected to the demultiplexer 20 via a transmission line. The demultiplexer 20 is connected to the first matching device 31 and to the second matching device 32 each via a transmission line. The first matching device 31 is connected to the plasma generating electrode 51 via a transmission line. The second matching device 32 is connected to the plasma generating electrode 52 via a transmission line.

The first and second matching devices 31 and 32 correspond to the first and second frequencies respectively and match the impedance of the plasma load to the impedance of the RF power supply 1. The first matching device 31 is connected to the first filter 21 via a transmission line, and the second matching device 32 is connected to the second filter 22 via a transmission line.

When RF power in the first frequency is supplied by the RF power supply 1, only the first filter 21 in the demultiplexer 20 passes the RF power. So, the RF power is supplied only to the plasma generating electrode 51. In this case, the impedance of the RF power supply 1 outputting RF power in the first frequency and the impedance of the plasma load are matched by the first matching device 31.

When RF power in the second frequency is supplied by the RF power supply 1, only the second filter 22 in the demultiplexer 20 passes the RF power. So, the RF power is supplied only to the plasma generating electrode 52. In this case, the impedance of the RF power supply 1 outputting RF power in the second frequency and the impedance of the plasma load are matched by the second matching device 32.

Thus, in the impedance matching device 2A of this embodiment, as the demultiplexer 20 changes the path of RF power depending on the frequency of the RF power, the frequency of the RF power output from the RF power supply 1 can be switched without causing momentary interruptions in the RF power supplied to the plasma generating electrodes 51 and 52.

In the present embodiment, a diplexer is used for the demultiplexer 20 that demultiplexes RF power into two frequency bands. Alternatively, for example, a triplexer that demultiplexes RF power into three frequency bands may be used for the demultiplexer 20 as long as the RF power is demultiplexed into two or more frequency bands. The demultiplexer 20 has to be a one that exclusively demultiplexes the RF power of multiple frequencies that is selectively output from the RF power supply 1 and outputs each demultiplexed RF power from different transmission paths.

### Second Embodiment

A plasma generating apparatus for a second embodiment is described. FIG. 2 is a block diagram of the plasma generating apparatus for the second embodiment.

As shown in FIG. 2, the plasma generating apparatus of the present embodiment differs from that of the first embodiment in that it has an impedance matching device 2B instead of the impedance matching device 2A, and one plasma generating electrode 50 instead of two plasma generating electrodes 51 and 52. The impedance matching device 2B differs from the impedance matching device 2A in that it further includes a multiplexer 40.

The multiplexer 40 is configured as a diplexer as with the demultiplexer 20, and has a third filter 41 that passes only RF power in a frequency band that includes the first frequency and a fourth filter 42 that passes only RF power in another frequency band that includes the second frequency. The third filter 41 is connected to the first matching device 31 via a transmission line, and the fourth filter 42 is connected to the second matching device 32 via a transmission line. The third filter 41 and the fourth filter 42 are connected to the plasma generating electrode 50 via a transmission line.

When RF power in the first frequency is supplied by the RF power supply 1, the RF power passes through the third filter 41 of the multiplexer 40 and is supplied to the plasma generating electrode 50. When RF power in the second frequency is supplied by the RF power supply 1, the RF power passes through the fourth filter 42 of the multiplexer 40 and is supplied to the plasma generating electrode 50.

Thus, by disposing the multiplexer 40 between the first and second matching devices 31, 32 and the plasma generating electrode 50, the plasma generating electrode 50 can be shared between the RF power of the first frequency and that of the second frequency in plasma generation.

As with the demultiplexer 20, the multiplexer 40 may be a triplexer. The multiplexer 40 has to be a one that mixes the RF power of multiple frequencies selectively output by the RF power supply 1 and outputs from a single transmission path.

A plasma generating apparatus disposed with the impedance matching device 2A or 2B according to the embodiments shown above may be utilized, for example, in semiconductor device fabrication.

The embodiment of the present invention has been presented by way of example only, and is not intended to limit the scope of the invention. The novel embodiment described herein may be embodied in a variety of other forms; furthermore, various omissions, substitutions and changes may be made without departing from the spirit of the invention. The embodiment and modifications are included in the scope or spirit of the present invention and in the appended claims and their equivalents.

### REFERENCE SIGNS LIST

1: RF power supply
2A, 2B: Impedance matching devices
20: Demultiplexer
31, 32: First and second matching devices
50, 51, 52: Plasma generating electrodes

1. An impedance matching device connected between one or more plasma generating electrodes and a radiofrequency (RF) power supply that selectively supplies RF power of multiple frequencies, comprising:
multiple matching devices each of which corresponds to each frequency of the multiple frequencies of the RF power, and matches an impedance of the RF power supply to an impedance of a plasma load; and
a demultiplexer that demultiplexes the RF power of multiple frequencies output by the RF power supply to yield demultiplexed RF power and feeds each of the demultiplexed RF power to a corresponding matching device in the multiple matching devices.

2. The impedance matching device of claim 1, further comprising:
a multiplexer disposed between the multiple matching devices and the one or more plasma generating electrodes that mixes the RF power of multiple frequencies to yield mixed RF power and outputs the mixed RF power from a single transmission path to the one or more plasma generating electrodes.
